(19) United States
(12) Patent Application Publication
(10) Pub. No.: US 2015/0130027 A1
(43) Pub. Date: May 14, 2015

(54) METHOD OF FORMING CARBON-CONTAINING THIN FILM AND METHOD OF MANUFACTURING SEMICONDUCTOR DEVICE BY USING THE METHOD

(71) Applicant: Samsung Electronics Co., Ltd., Suwon-si (KR)

(72) Inventors: Se jun PARK, Seoul (KR); Ho jun KIM, Gwacheon-si (KR); Jaihyung WON, Seoul (KR); Gyuwan CHOI, Hwaseong-si (KR); Dohyung KIM, Uijeongbu-si (KR)

(21) Appl. No.: 14/538,100

(22) Filed: Nov. 11, 2014

(30) Foreign Application Priority Data
Nov. 13, 2013 (KR) 10-2013-0137887

(51) Int. Cl. H01L 21/308; H01L 21/311; H01L 29/06; H01L 21/033

(52) U.S. Cl. CPC H01L 21/3086; H01L 21/0337; H01L 21/0332; H01L 21/0338; H01L 21/31144; H01L 21/3081; H01L 21/3088; H01L 29/0692
USPC 257/618; 438/778; 438/702; 257/632

(57) ABSTRACT

A method of forming a carbon-containing thin film and a method of manufacturing a semiconductor device using the method of forming the carbon-containing thin film are described. The method of forming a carbon-containing thin film includes the steps of introducing a substrate into a chamber, injecting hydrocarbon gas and at least nitrogen gas simultaneously into the chamber, and depositing a carbon-containing thin film including carbon and nitrogen on the substrate, thereby forming a carbon-containing thin film having high selectivity and uniform thickness.

### CROSS-REFERENCE TO RELATED APPLICATIONS

This application claims the benefit of Korean Patent Application No. 10-2013-0137887, filed on Nov. 13, 2013, in the Korean Intellectual Property Office, the disclosure of which is incorporated herein in its entirety by reference.

### BACKGROUND

The inventive concept relates to a method of forming an etch mask and a method of manufacturing a semiconductor device by using the method of forming an etch mask, and more particularly, to a method of forming a carbon-containing thin film and a method of manufacturing a semiconductor device by using the method of forming the carbon-containing thin film.

As semiconductor devices have become more highly integrated, patterns have become finer. To form micro-patterns, it is necessary to form a relatively thick etch mask in order to secure a desired etching resistance, or it is necessary to use an etch mask with high etching selectivity. However, when mask materials are used to form relatively thick etch masks, the manufacturing processes are complicated and the unit cost per mask is high. Thus, appropriate methods of forming a material or mask having high etching selectivity are required.

In addition, in micro-patterning, errors easily occur in micro-patterns even when a small difference in an overall thickness of an etching target layer exists. Thus, to prevent the occurrence of such errors in micro-patterns, a thin film used as a mask needs to have a uniform thickness over an entire surface of an etching target layer.

### SUMMARY

The inventive concept provides a method of forming a carbon-containing thin film having high selectivity and uniform thickness, whereby the micro-patterns formed using these thin films may be transferred without errors. The inventive concept further includes a method of manufacturing a semiconductor device by using the method of forming the carbon-containing thin film.

In a method according to the inventive concept, hydrocarbon gas and nitrogen gas are added together as reactants when forming a carbon-containing thin film.

As technical solutions, embodiments of the inventive concept are provided.

According to an aspect of the inventive concept, there is provided a method of forming a thin film, including introducing a substrate into a chamber, injecting hydrocarbon gas and nitrogen gas simultaneously into the chamber, and depositing a carbon-containing thin film comprising carbon and nitrogen on the substrate.

An amount of nitrogen relative to carbon included in the carbon-containing thin film may range from about 0.05 at % to about 5.00 at %.

The method may further include generating plasma in the chamber containing the substrate between the steps of injecting the gases and depositing the thin film.

In the injecting step, oxygen gas may also be injected into the chamber.

In the injecting step, at least one inert gas may also be injected into the chamber.

The hydrocarbon gas may be at least one of C₂H₂ gas, C₂H₄ gas, and C₆H₁₂ gas.

The carbon-containing thin film that is deposited on the substrate may include an amorphous carbon layer.

According to another aspect of the inventive concept, there is provided a method of manufacturing a semiconductor device, including the steps of: forming a carbon-containing thin film on an etching target layer by simultaneously injecting hydrocarbon gas and nitrogen gas into a chamber; forming a resist layer on the carbon-containing thin film; forming a resist pattern by exposing the resist layer to light and developing the exposed resist layer; forming a carbon-containing thin film pattern to partially expose the etching target layer by selectively etching the carbon-containing thin film according to the resist pattern; and etching a portion of the exposed etching target layer by using the carbon-containing thin film pattern as an etch mask.

In a method of manufacturing a semiconductor device, the etching target layer may be a substrate.

The method may further include the step of forming the etching target layer on a substrate before the step of forming the carbon-containing thin film, wherein the etching target layer is a conductive layer, an insulating layer, or a semiconductor layer.

The method may further include the step of forming an anti-reflective film on the carbon-containing thin film between the step of forming the carbon-containing thin film and the step of forming the resist layer.

The method may further include the step of forming at least one material layer having different etching properties than the carbon-containing thin film between the step of forming the carbon-containing thin film and the step of forming the resist layer, and the step of forming a material layer pattern to partially expose the carbon-containing thin film by selectively etching the material layer according to the resist pattern between the step of forming the resist pattern and the step of forming the carbon-containing thin film pattern.

In an aspect a method of forming a thin film comprises the steps of: introducing a substrate into a chamber; injecting hydrocarbon gas and nitrogen gas simultaneously into the chamber; and depositing a carbon-containing thin film comprising carbon and nitrogen on the substrate.

In some embodiments the method includes a step of depositing the carbon-containing thin film where an amount of nitrogen to carbon included in the carbon-containing thin film ranges from about 0.05 at % to about 5.00 at %.

In some embodiments the method further comprises a step of generating plasma in the chamber between the injecting and the depositing steps.

In some embodiments the method includes an injecting step in which oxygen gas is also injected into the chamber.

In some embodiments the method also includes an injecting step in which at least one inert gas is also injected into the chamber.

In some embodiments of the method, the hydrocarbon gas comprises at least one of an aliphatic hydrocarbon compound, an aromatic hydrocarbon compound, and derivatives thereof.

In some embodiments of the method, the hydrocarbon gas comprises a hydrocarbon gas having a triple chemical bond.

In some embodiments of the method, the hydrocarbon gas is at least one of C₂H₂ gas, C₂H₄ gas, and C₆H₁₂ gas.

In some embodiments of the method, the carbon-containing thin film comprises an amorphous carbon layer.

In another aspect a method of manufacturing a semiconductor device comprises the steps of: forming a carbon-containing thin film on an etching target layer by simultaneously injecting hydrocarbon gas and nitrogen gas into a chamber; forming a resist layer on the carbon-containing thin film; forming a resist pattern by exposing the resist layer to light and developing the exposed resist layer; forming a carbon-containing thin film pattern to partially expose the etching target layer by selectively etching the carbon-containing thin film according to the resist pattern; and

etching a portion of the exposed etching target layer by using the carbon-containing thin film pattern as an etch mask.

In some embodiments of the method, the step of forming the carbon-containing thin film includes also injecting oxygen gas into the chamber.

In some embodiments of the method, the etching target layer is a substrate.

In some embodiments, the method includes a step of forming the etching target layer on a substrate before the step of forming the carbon-containing thin film, wherein the etching target layer is a conductive layer, an insulating layer, or a semiconductor layer.

In some embodiments, the method includes a step of forming an anti-reflective film on the carbon-containing thin film between the step of forming the carbon-containing thin film and the step of forming the resist layer.

In some embodiments, the method includes the steps of: forming at least one material layer having different etching properties than the carbon-containing thin film between the step of forming the carbon-containing thin film and the step of forming the resist layer; and also forming a material layer pattern to partially expose the carbon-containing thin film by selectively etching the material layer according to the resist pattern between the step of forming the resist pattern and the step of forming the carbon-containing thin film pattern.

In another aspect, a component for use in semiconductor fabrication comprises a carbon-containing thin film having high selectivity and high thickness uniformity deposited on a substrate, the component being formed according to the method of introducing a substrate into a chamber; injecting hydrocarbon gas and nitrogen gas simultaneously into the chamber; and depositing a carbon-containing thin film comprising carbon and nitrogen on the substrate.

In some embodiments the component is formed by a method that includes a step of adding oxygen gas or an inert gas to the chamber together with the hydrocarbon gas and nitrogen gas.

In another aspect, a semiconductor device is fabricated using a thin film having high selectivity and high thickness uniformity, the device being formed according to the method of: forming a carbon-containing thin film on an etching target layer by simultaneously injecting hydrocarbon gas and nitrogen gas into a chamber; forming a resist layer on the carbon-containing thin film; forming a resist pattern by exposing the resist layer to light and developing the exposed resist layer; forming a carbon-containing thin film pattern to partially expose the etching target layer by selectively etching the carbon-containing thin film according to the resist pattern; and

etching a portion of the exposed etching target layer by using the carbon-containing thin film pattern as an etch mask.

In some embodiments the semiconductor device is formed by a method that includes a step of forming the carbon-containing thin film in which oxygen gas or an inert gas is added to the chamber together with the hydrocarbon gas and nitrogen gas.

In another aspect a method of forming a highly integrated semiconductor device substantially free of micro-patterning errors comprises the steps of forming a thin film on an etching target layer, etching the thin film to form an etched mask, and etching the target layer using the etched mask, including the improvement wherein the step of forming a carbon-containing thin film on the etching target layer includes adding hydrocarbon gas and nitrogen gas into a chamber containing the target layer under plasma conditions.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart for explaining a method of forming a carbon-containing thin film, according to an embodiment of the inventive concept;

FIG. 2 is a schematic view illustrating a deposition device (including a chamber, and with nitrogen gas and hydrocarbon gas being injected into the chamber) used in a method of forming a carbon-containing thin film;

FIG. 3 is a schematic view illustrating a diffusion aspect of the hydrocarbon and nitrogen gases that are injected into the chamber in a method of forming a carbon-containing thin film;

FIGS. 4 to 6 are schematic cross-sectional views sequentially illustrating a process of forming a carbon-containing thin film from nitrogen and hydrocarbon in a method of forming a carbon-containing thin film;

FIG. 7 is a schematic view illustrating a deposition device (including a chamber, and a plasma state of the materials injected into the chamber) used in a method of forming a carbon-containing thin film;

FIG. 8 is a graph showing a relationship between light absorptivity k of a thin film formed using a method of forming a carbon-containing thin film and a flow rate of the nitrogen gas used in the method;

FIG. 9 is a graph showing a relationship between thickness uniformity of the thin film formed using a method of forming a carbon-containing thin film and the flow rate of the nitrogen gas used in the method;

FIG. 10 is a graph showing a relationship between light absorptivity k of the thin film formed using a method of forming a carbon-containing thin film and a flow rate ratio of nitrogen gas to propylene (C₃H₆) gas;

FIG. 11 is a graph showing a relationship between thickness uniformity of the thin film formed using a method of forming a carbon-containing thin film and the flow rate ratio of nitrogen gas to propylene (C₃H₆) gas;

FIG. 12 is a schematic view illustrating a deposition device (including a chamber, and with nitrogen gas, hydrocarbon gas and oxygen gas being injected into the chamber) used in a method of forming a carbon-containing thin film;

FIGS. 13 to 15 are schematic cross-sectional views sequentially illustrating a process of forming a carbon-containing thin film from nitrogen, hydrocarbon, and oxygen in a method of forming a carbon-containing thin film;

FIG. 16 is a graph showing a relationship between light absorptivity k of the thin film formed using a method of forming a carbon-containing thin film and a flow rate of oxygen gas used in the method;

FIG. 17 is a graph showing a relationship between thickness uniformity of the thin film formed using a method of forming a carbon-containing thin film and the flow rate of oxygen gas used in the method;

FIG. 18 is a graph showing a relationship between light absorptivity k of the thin film formed using a method of forming a carbon-containing thin film and a flow rate ratio of oxygen gas to propylene (C₃H₆) gas, and also showing a relationship between deposition rate and the flow rate ratio of oxygen gas to propylene (C₃H₆) gas;

FIG. 19 is a schematic view illustrating a deposition device (including a chamber, and with substances being injected into the chamber) used in a method of forming a carbon-containing thin film;

FIG. 20 is a flowchart for explaining a method of manufacturing a semiconductor device, according to an embodiment of the inventive concept;

FIGS. 21A to 21E are schematic cross-sectional views sequentially illustrating an etching process using a carbon-containing thin film in a method of manufacturing a semiconductor device;

FIGS. 22A to 22E are schematic cross-sectional views sequentially illustrating another etching process using a carbon-containing thin film in a method of manufacturing a semiconductor device;

FIGS. 23A to 23E are schematic cross-sectional views sequentially illustrating another etching process using a carbon-containing thin film in a method of manufacturing a semiconductor device; and

FIGS. 24A to 24E are schematic cross-sectional views sequentially illustrating another etching process using a carbon-containing thin film in a method of manufacturing a semiconductor device.

### DETAILED DESCRIPTION OF THE EMBODIMENTS

Embodiments of the inventive concept described with reference to the accompanying drawings may have many different forms, and it should be understood that the scope of the inventive concept is not limited by the embodiments set forth herein. For example, variations in the shapes of the illustrations as a result, for example, of manufacturing techniques and/or tolerances, are to be expected. Thus, embodiments of the inventive concept should not be construed as limited to the particular shapes of regions illustrated herein but are to include variations in shapes that result, for example, from manufacturing. The same reference numerals refer to the same elements throughout the drawings, and thus a detailed description thereof is only provided the first time the element is described. Further, a variety of elements and regions in the drawings are schematically illustrated. Thus, it should be understood that the inventive concept is not limited to the relative sizes or intervals shown in the accompanying drawings.

The terminology used herein is for the purpose of describing particular embodiments only and is not intended to be limiting of the inventive concept. As used herein, the singular forms are intended to include the plural forms as well, unless the context clearly indicates otherwise. It will be further understood that the terms “comprises” and/or “comprising,” when used in this specification, specify the presence of stated features, integers, steps, operations, elements, components, or combinations thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept pertains. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Expressions such as “at least one of” when preceding a list of elements, modify the entire list of elements and do not modify the individual elements of the list.

Hereinafter, exemplary embodiments of the inventive concept will be described in detail with reference to the accompanying drawings. The drawings illustrate relevant parts of semiconductor devices according to embodiments of the inventive concept. In the inventive concept, methods of forming a carbon-containing thin film are described for illustrative purposes only and detailed descriptions of some operations/steps thereof are omitted herein.

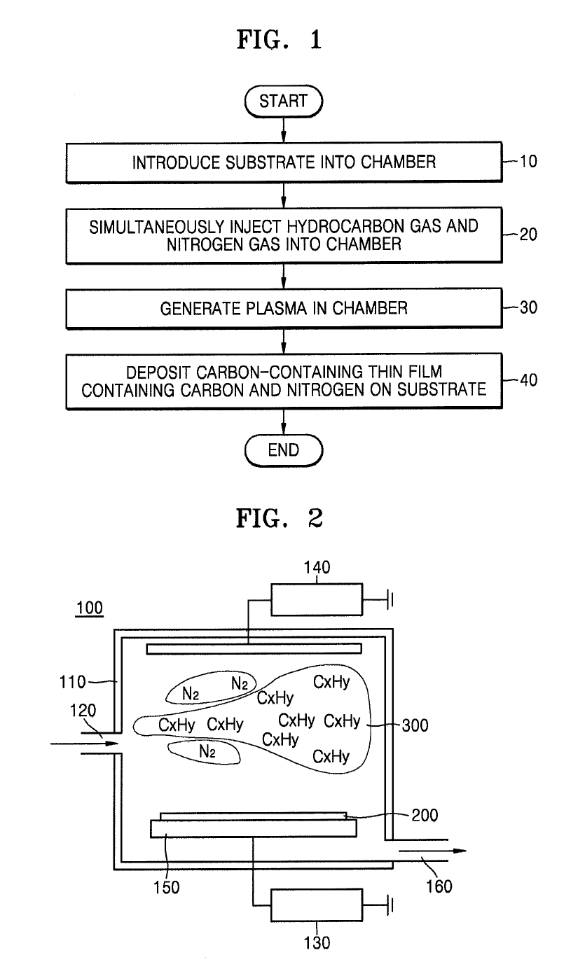

FIG. 1 is a flowchart for explaining a method of forming a carbon-containing thin film, according to an embodiment of the inventive concept.

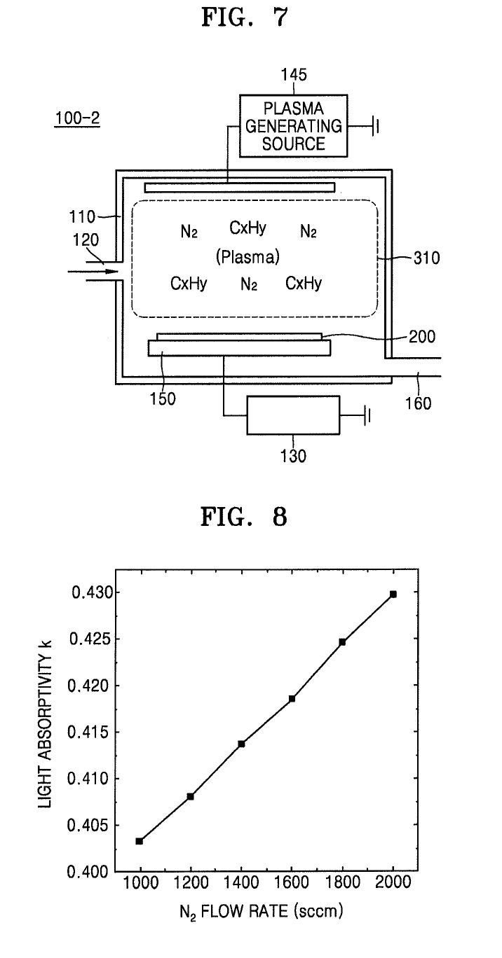

Referring to FIG. 1, a substrate is introduced into a chamber (operation 10). Then, hydrocarbon gas and nitrogen gas are simultaneously injected into the chamber (operation 20). Operation 30 (plasma generation) will be described below with reference to FIG. 7. Then, a carbon-containing thin film containing carbon and nitrogen is deposited on the substrate (operation 40).

In operation 20, the simultaneous injection of the hydrocarbon gas and the nitrogen gas should be distinguished from sequential injection of these gases because there are differences in the results of simultaneous versus sequential injections. However, as described below in another embodiment, a flow rate of nitrogen gas or oxygen gas (hereinafter also referred to as an “additive gas”) is limited. As a result, the hydrocarbon gas and the additive gas may not be simultaneously injected. In some embodiments, the additive gas may first be injected and then the hydrocarbon gas may be injected. In another embodiment, the hydrocarbon gas may first be injected and then the additive gas may be injected. In another embodiment, the hydrocarbon gas and the additive gas may be alternately injected. In another embodiment, the additive gas may be injected while deposition of the hydrocarbon gas is progressing. In another embodiment, the hydrocarbon gas may be injected while deposition of the additive gas is progressing. Thus, there is no limitation regarding the injection order of the hydrocarbon gas and the additive gas although there may be differences resulting from these alternative embodiments.

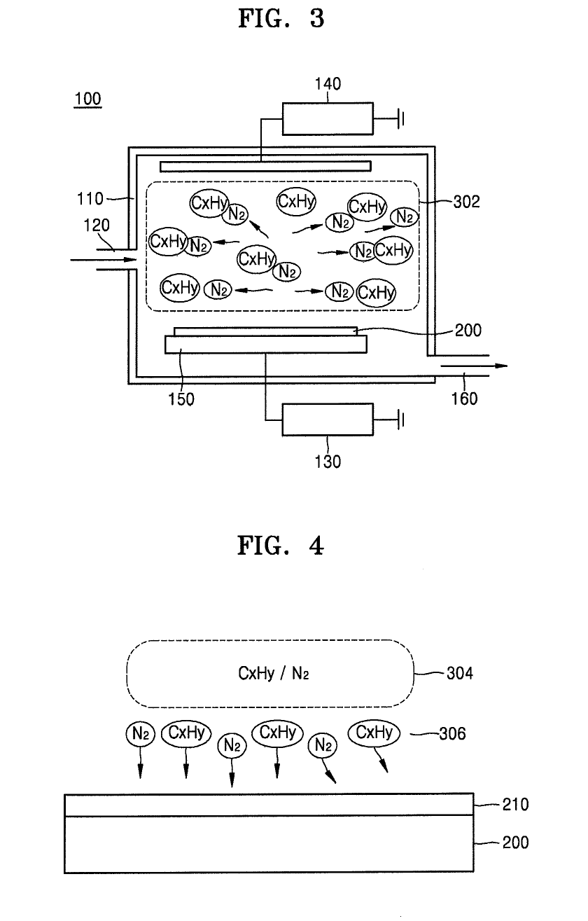

The nitrogen gas diffuses more easily than do other carrier gases, e.g., an inert gas such as Ar gas, He gas, and the like. Thus, the use of nitrogen may enable the hydrocarbon gas to be more uniformly diffused in a chamber. Such diffusion facilitates more uniform deposition of hydrocarbon over the entire surface of an etching target layer. Next, gas injection and diffusion processes according to an embodiment will be described with reference to FIGS. 2 and 3.

In FIGS. 2 to 7, 12 to 15, and 19, like reference numerals denote like elements.

FIG. 2 is a schematic view illustrating a deposition device 100 (including a chamber 110, with nitrogen gas and hydrocarbon gas being injected into the chamber) used in a method of forming a carbon-containing thin film.

Referring to FIG. 2, the deposition device 100 may include the chamber 110, a gas supply hole 120, a power supply 130, a plasma-generating power supply 140, a substrate support body 150 to support a substrate 200, and a chamber outlet 160 that operates together with a vacuum pump to remove an unnecessary material from the chamber 110.

The substrate 200 may be introduced into the deposition device 100, and hydrocarbon gas 300 and nitrogen gas (shown but not separately numbered) may then be simultaneously injected via the gas supply hole 120. However, the injected hydrocarbon gas 300 does not diffuse well and thus may diffuse non-uniformly in the chamber 110 according to an initial hydrocarbon gas injection direction and gas flow rate. Under these conditions, a uniform carbon-containing thin film may not form on the substrate 200. When the nitrogen gas is injected together with the hydrocarbon gas 300, however, as described below with reference to FIG. 3, the nitrogen gas may enable the hydrocarbon gas 300 to more uniformly diffuse throughout the chamber 110.

FIG. 3 is a schematic view illustrating a diffusion aspect of the hydrocarbon and nitrogen gases injected into the chamber in a method of forming a carbon-containing thin film.

Referring to FIG. 3, since the nitrogen gas injected together with the hydrocarbon gas is highly diffusible, the nitrogen gas may enable the hydrocarbon gas to more uniformly diffuse throughout the chamber 110. A mixed gas 302 comprising the hydrocarbon gas and the nitrogen gas uniformly diffuses in the chamber 110 and thus results in a more uniform deposition on the substrate 200.

FIGS. 4 to 6 are cross-sectional views illustrating a process of forming a carbon-containing thin film from nitrogen and hydrocarbon in a method of forming a carbon-containing thin film.

Referring to FIG. 4, an etching target layer 210 may be formed on the substrate 200. A gas portion 306 of the mixed gas 302 comprising uniformly diffused hydrocarbon gas and nitrogen gas may be deposited on the etching target layer 210 formed on the substrate 200.

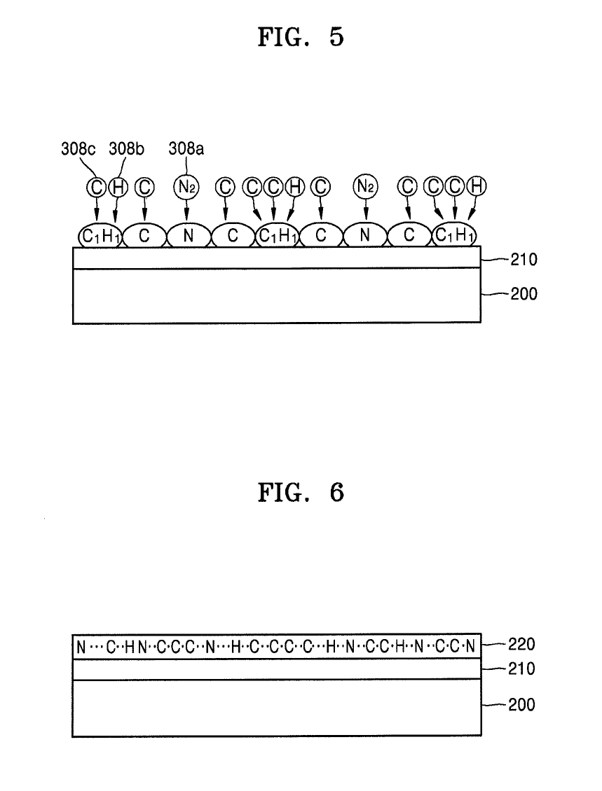

FIG. 5 illustrates partial deposition of nitrogen 308a, hydrogen 308b, and carbon 308c atoms of the injected gases on the etching target layer 210.

FIG. 6 illustrates a carbon-containing thin film 220 obtained after completing deposition of nitrogen, carbon and hydrogen atoms on the etching target layer 210.

In some embodiments of the inventive concept, a process of heat-treating the carbon-containing thin film may further be performed after operation 40 (FIG. 1). A more stable carbon-containing thin film may be formed by this heat-treating step.

A process of forming a carbon-containing thin film with enhanced uniformity by simultaneously adding the hydrocarbon gas and the nitrogen gas to the chamber has been described above. The nitrogen gas injected into the chamber together with hydrocarbon gas is partially deposited together with the hydrocarbon gas when the carbon-containing thin film is formed; and, this results in changes in components of the carbon-containing thin film. A carbon-containing thin film containing nitrogen, as a result of simultaneous injection of hydrocarbon and nitrogen into the chamber, provides higher selectivity than a carbon-containing thin film without nitrogen. When such a thin film containing nitrogen is used as an etch mask, the etching target layer 210 under the thin film may be sufficiently etched to a desired depth.

Referring back to FIG. 1, in an embodiment of the inventive concept, the method may further include a step of generating plasma in the chamber (operation 30) between operations 20 and 40.

FIG. 7 is a schematic view illustrating a deposition device 100-2 including a chamber 110 and with the materials injected into the chamber 110 in a plasma state in a method of forming a carbon-containing thin film.

Referring to FIG. 7, the deposition device 100-2 includes the chamber 110, a gas injection hole 120, a chamber outlet 160 that operates together with a vacuum pump, a substrate support body 150, a power supply 130, and a plasma generating source 145. A mixed gas of injected hydrocarbon and nitrogen gases is converted to a plasma state 310 by the plasma generating source 145, and a carbon-containing thin film is formed on the substrate 200.

In some embodiments of the inventive concept, the deposition device 100-2 may be a plasma enhanced chemical vapor deposition (PECVD) device, a low pressure chemical vapor deposition (LPCVD) device, a very low pressure chemical vapor deposition (VLPCVD) device, an ultra-high-vacuum chemical vapor deposition (UHVCVD) device, a rapid thermal chemical vapor deposition (RTCVD) device, an atmospheric pressure chemical vapor deposition (APCVD) device, a physical vapor deposition (PVD) device, or a plasma-enhanced chemical vapor deposition (PECVD) device. In this case, deposition equipment using plasma may use a capacitively coupled plasma (CCP) source, an inductively coupled plasma (ICP) source, or the like. The PVD device may use deposition equipment selected from among a vacuum deposition device, a sputtering device, and an ion-plating device.

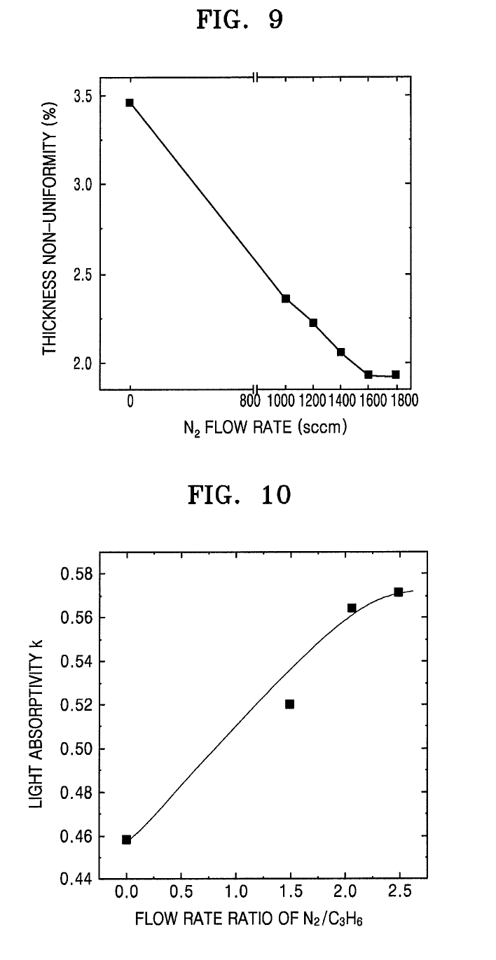

FIGS. 8 and 9 are graphs illustrating how selectivity characteristics and thickness uniformity over the entire surface of the thin film vary according to a flow rate of nitrogen gas.

FIG. 8 is a graph showing a relationship between a light absorptivity k of the thin film formed using a method of forming a carbon-containing thin film and the flow rate of the nitrogen gas used in the same method.

The light absorptivity k denotes the amount of sp2 present in a substance. That is, as the amount of sp2 present in a substance increases so too does the light absorptivity k. As an amount of sp2 in a substance increases, the substance has a higher etching resistance and thus an etching selectivity is increased. Thus, the etching selectivity of a substance may be indirectly measured through the light absorptivity k, and a higher light absorptivity k may be regarded as indicating high selectivity.

Referring to the graph of FIG. 8, the light absorptivity k of the thin film increases more or less linearly in proportion to an increase in the flow rate of the nitrogen gas. It can be confirmed that the etching selectivity also increases as the flow rate of the nitrogen gas increases.

FIG. 9 is a graph showing a relationship between a thickness non-uniformity of the thin film formed using a method of forming a carbon-containing thin film using nitrogen and the flow rate of the nitrogen gas used in the same method.

Referring to the graph of FIG. 9, a thickness uniformity prior to injection of the nitrogen gas is only about 3.5%, and, thus, there is high probability of errors occurring when forming micro-patterns. However, after injection of the nitrogen gas, the thin film exhibits a thickness non-uniformity of approximately 2.3% at a flow rate of the nitrogen gas of about 1000 sccm; and, the thickness non-uniformity further decrease to about 1.9% at a flow rate of the nitrogen gas of about 1600 sccm or greater. This confirms that the thin film has enhanced thickness uniformity, which satisfies a requirement for thickness uniformity of a thin film for formation of micro-patterns.

Referring to the graphs of FIGS. 8 and 9, the flow rate of the nitrogen gas may be selected within a range of about 1000 sccm to about 5000 sccm using a chamber having a volume of about 1128 cm³ (and the same for other examples herein). In this case, a thickness non-uniformity of the thin film is about 1.9% to about 2.3%, which indicates that the thin film according to the inventive concept exhibits an decrease in thickness non-uniformity of about 0.5 to about 0.6 times that of a conventional thin film having a thickness non-uniformity of about 3.5% or greater. Referring to FIG. 8, the increase in etching selectivity is proportionate to the increase in the flow rate of the nitrogen gas. The range of flow rates of the nitrogen gas selected according to the thickness uniformity is illustrated in FIG. 9.

Referring to the graph of FIG. 9, the thin film has a thickness non-uniformity of 1.9% to 2.3% at a flow rate of the nitrogen gas within a relatively small range of about 1000 sccm to about 1600 sccm. Considering that a thin film without nitrogen gas has a thickness non-uniformity of about 3.5% or greater, the graph of FIG. 9 indicates that, when the flow rate of the nitrogen gas is less than about 1000 sccm, the thickness non-uniformity of the resulting thin film may increase.

On the other hand, when the flow rate of the nitrogen gas is about 5000 sccm or greater, it has been found that a deposition efficiency may be reduced because of an increase in an inner pressure in the chamber and a decrease in a deposition rate.

Thus, a flow rate of nitrogen gas between about 1000 sccm to about 5000 sccm may be optimum for some embodiments. However, it will be understood that gas flow rate ranges according to the inventive concept are not limited to those described above.

FIG. 10 is a graph showing a relationship between a light absorptivity k of the thin film formed using a method of forming a carbon-containing thin film using nitrogen and a flow rate ratio of nitrogen gas to propylene (C₃H₆) gas.

The relationship between the light absorptivity k of the carbon-containing thin film and the etching selectivity of that thin film has already been described above.

Referring to the graph of FIG. 10, the light absorptivity k of the thin film increases more or less linearly in proportion to an increase in the flow rate of the nitrogen gas injected, at least up to a point. A variation in the light absorptivity k is sharply reduced, however, when the flow rate ratio of nitrogen gas to propylene (C₃H₆) gas approaches around 2.5, and a further increase in the flow rate of the nitrogen gas does not further increase the light absorptivity k.

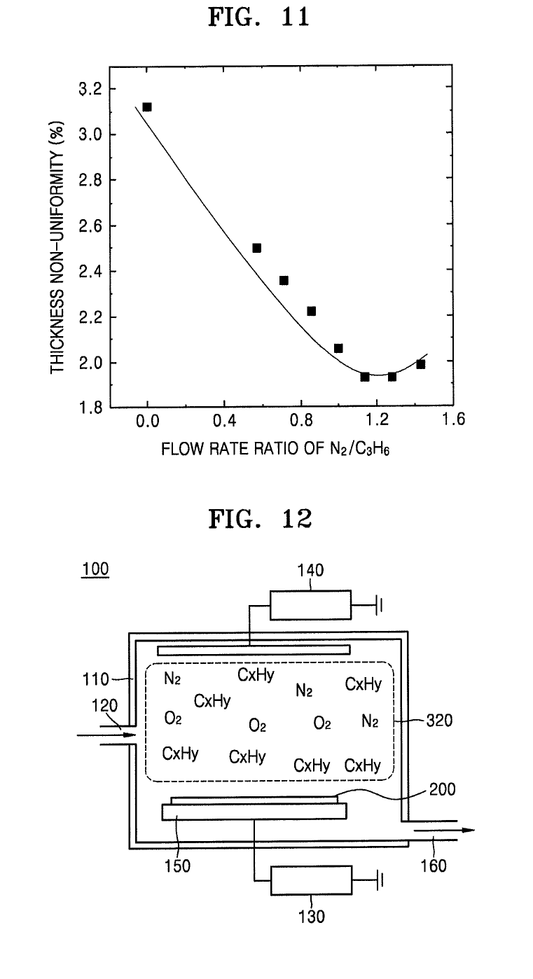

FIG. 11 is a graph showing a relationship between a thickness non-uniformity of the thin film formed using a method of forming a carbon-containing thin film using nitrogen and a flow rate ratio of nitrogen gas to propylene (C₃H₆) gas.

Referring to the graph of FIG. 11, the thin film has a thickness non-uniformity of about 1.9% to about 2.3% when the flow rate ratio of nitrogen gas to propylene (C₃H₆) gas is about 0.8 to about 1.6, which indicates that the thin film has an decrease in thickness non-uniformity of about 0.5 to about 0.6 times that (i.e., about 3.5%) of a thin film formed using lower flow rate ratios of nitrogen to propylene.

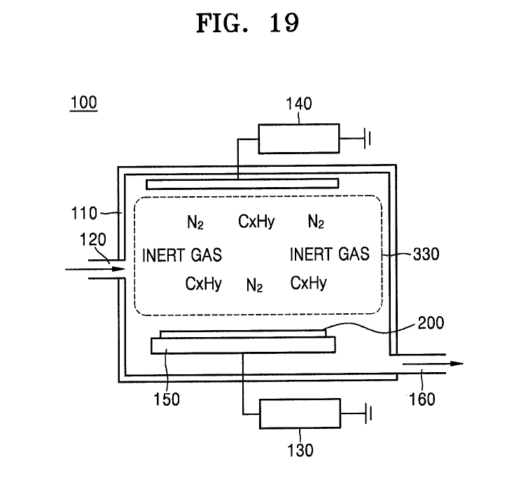

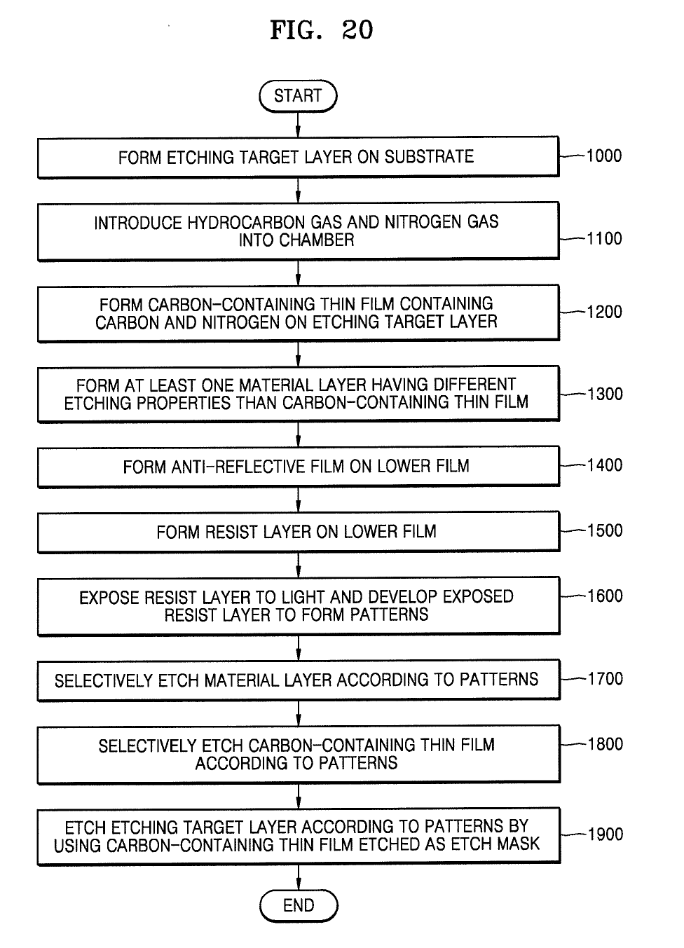

Referring to the graphs of FIGS. 10 and 11, when the flow rate of the nitrogen gas to hydrocarbon gas is about 0.8 to about 2.0, a carbon-containing thin film may be formed. As described below with reference to FIGS. 19 and 20, when the flow rate of the nitrogen gas to hydrocarbon gas is in this desirable range, a thickness non-uniformity of the thin film may be about 1.9% to about 2.3%, which indicates that the thin film according to the inventive concept has decreased thickness non-uniformity that is about 0.5 to about 0.6 times that of a conventional thin film having a thickness non-uniformity of about 3.5% or greater. Also, the light absorptivity k linearly increases at a flow rate ratio of nitrogen gas to hydrocarbon gas of about 0.8 to about 2.0. Thus, an appropriate thickness uniformity and high selectivity may be obtained using process parameters within the above-described ranges.

Referring back to FIG. 1, in some embodiments of the inventive concept, oxygen gas may further be injected during operation 20.

FIG. 12 is a schematic view illustrating a deposition device 100 (including a chamber 110, with nitrogen gas, hydrocarbon gas and oxygen gas being injected into the chamber) used in a method of forming a carbon-containing thin film.

Referring to FIG. 12, a mixed gas 320 including nitrogen gas, oxygen gas, and hydrocarbon gas uniformly diffuses in the chamber 110. Oxygen gas is relatively highly diffusible and thus may contribute to a more complete diffusion of the hydrocarbon gas. As described above, nitrogen gas is also highly diffusible.

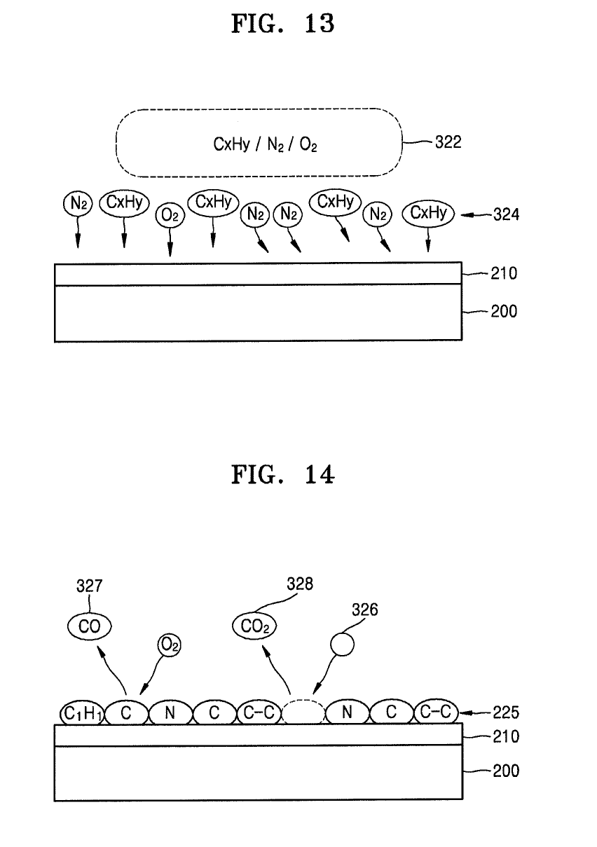

FIGS. 13 to 15 are cross-sectional views sequentially illustrating a process of forming a carbon-containing thin film from nitrogen, hydrocarbon, and oxygen in a method of forming a carbon-containing thin film.

Referring to FIG. 13, the etching target layer 210 is deposited on the substrate 200. A gas portion 324 of a mixed gas 322 comprising hydrocarbon gas, nitrogen gas, and oxygen gas, is uniformly diffused over the etching target layer 210 resulting in deposits of these substances on the etching target layer 210 deposited on the substrate 200.

Referring to FIG. 14, nitrogen, carbon and hydrogen components of the injected gases are shown as being partially deposited on the etching target layer 210 on the substrate 200, thereby forming a carbon-containing thin film 225. In this regard, some of the carbon present in a weakly bonded portion of the carbon-carbon bonds of the carbon-containing thin film 225 reacts with oxygen 326 to form carbon monoxide 327 or carbon dioxide 328, and the carbon monoxide 327 and/or the carbon dioxide 328 thus formed are gases that may be removed from the carbon-containing thin film 225. This process is implemented to increase a thickness uniformity by preventing damage that may occur after the carbon-containing thin film 225 is deposited by previously removing weak carbon-carbon bonds from the deposited carbon-containing thin film 225.

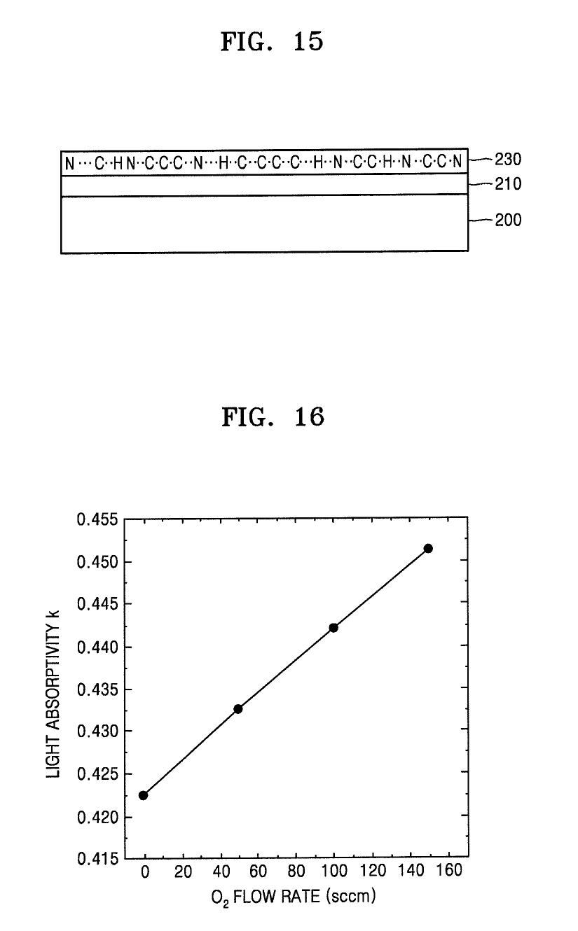

Referring to FIG. 15, deposition of a carbon-containing thin film 230 consisting of nitrogen, carbon, and hydrogen on the etching target layer 210 is completed. When oxygen gas is added together with nitrogen gas, a uniformity of the carbon-containing thin film is increased, which may further increase an etching selectivity of the resulting thin film.

In some embodiments of the inventive concept, a flow rate of nitrogen gas to oxygen gas may advantageously range from about 1:1.0 to 1:3.0.

FIG. 16 is a graph showing a relationship between light absorptivity k of the thin film formed using a method of forming a carbon-containing thin film using oxygen and nitrogen and a flow rate of oxygen gas used in the method.

The general relationship between light absorptivity k of the thin film and etching selectivity has already been described above.

Referring to the graph of FIG. 16, the light absorptivity k of the thin film increases linearly in proportion to an increase in the flow rate of oxygen gas. This confirms that a thin film with higher selectivity may be formed as the flow rate of oxygen gas increases.

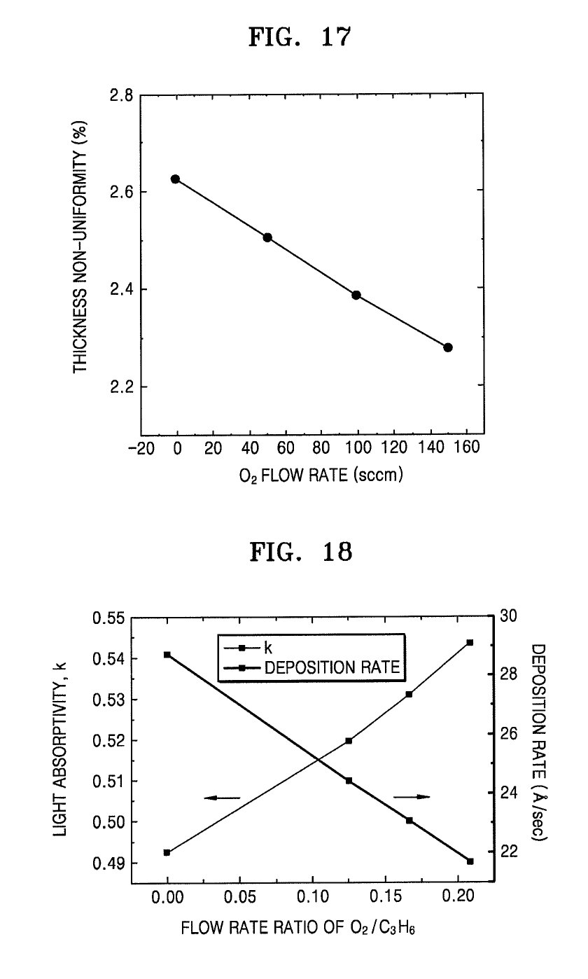

FIG. 17 is a graph showing a relationship between a thickness non-uniformity of a thin film formed using a method of forming a carbon-containing thin film using oxygen and nitrogen and the flow rate of oxygen gas used in the method.

Referring to the graph of FIG. 17, the thickness non-uniformity of the thin film decreases linearly in proportion to an increase in the flow rate of injected oxygen gas. This confirms that a thin film with improved overall uniform thickness may be formed as the flow rate of oxygen gas increases.

FIG. 18 is a graph showing a relationship between light absorptivity k of a thin film formed using a method of forming a carbon-containing thin film using oxygen and nitrogen and a flow rate ratio of oxygen gas to propylene (C₃H₆) gas, and also showing a relationship between deposition rate and the flow rate ratio of oxygen gas to propylene (C₃H₆) gas.

Referring to the graph of FIG. 18, the light absorptivity k of the thin film increases linearly in proportion to an increase in the flow rate of injected oxygen gas. This confirms that a carbon-containing thin film with improved overall uniform thickness may be formed as the flow rate of oxygen gas increases.

Referring to the graphs of FIGS. 16 to 18, as the flow rate of oxygen gas increases, a thickness uniformity and selectivity also increase. However, as illustrated in FIG. 18, a deposition rate of carbon decreases in proportion to an increase in the flow rate of oxygen gas. In particular, it has been found that film productivity may be reduced when the flow rate ratio of oxygen gas to propylene (C₃H₆) gas is about 0.4 or greater.

Referring to the graphs of FIGS. 16, 17 and 18, a flow rate ratio of nitrogen gas to hydrocarbon gas may advantageously range from about 0.001 to about 0.4.

Referring back to FIG. 1, in some embodiments of the inventive concept, at least one inert gas may further be injected during operation 20.

FIG. 19 is a schematic view illustrating a deposition device 100 (including a chamber 110, with several substances being injected into the chamber 110) used in a method of forming a carbon-containing thin film.

Referring to FIG. 19, a mixed gas 330 including nitrogen gas, an inert gas, and hydrocarbon gas uniformly diffuses in the chamber 110. Nitrogen gas and an inert gas such as He gas, Ar gas, or the like function as carrier gases to enable a more uniform diffusion of hydrocarbon in the chamber 110.

Referring back to FIG. 1, in some embodiments of the inventive concept, no inert gas is injected during operation 20. That is, nitrogen gas may be used alone as a carrier gas, or nitrogen gas and oxygen gas may be used as carrier gases without including any inert gas.

Referring again to FIG. 1, in some embodiments of the inventive concept, the hydrocarbon gas used in operation 20 may include at least one of an aliphatic hydrocarbon compound, an aromatic hydrocarbon compound, and derivatives thereof. In addition, the hydrocarbon gas may include at least one of the materials represented by the generic chemical formula CₓH_{y}, where x is a numeral from 1 to 10 and y is a numeral from 2 to 30. For example, the hydrocarbon gas may be a gas including at least one of aliphatic or aromatic hydrocarbon compounds such as acetylene (C₂H₂), propylene (C₃H₆), cyclohexane (C₆H₁₂), propyne (C₃H₄), propane (C₃H₈), butane (C₄H₁₀), butylene (C₄H₈), acetylene butadiene (C₄H₆), vinyl acetylene, phenyl acetylene, benzene, styrene, toluene, xylene, ethylbenzene, acetophenone, methyl benzoate, phenyl acetate, phenol, cresol, furan, monofluorobenzene, difluorobenzene, tetrafluorobenzene, hexafluorobenzene, and the like, derivatives thereof, hydrocarbon compounds partially or completely doped with or incorporating other ions such as fluorine-, oxygen-, hydroxyl group- and boron-containing derivatives, and derivatives thereof.

In some embodiments of the inventive concept, the hydrocarbon gas may include an acyclic hydrocarbon compound because a cyclic hydrocarbon, e.g., benzene (C₆H₆), is less reactive with nitrogen than an acyclic hydrocarbon, e.g., hexane (C₆H₁₄), having the same number of carbon atoms as benzene.

As described below, when hydrocarbon gas having a relatively low ratio of hydrogen to carbon is used as a source gas, the resulting thin film has a small number of carbon-hydrogen bonds and, thus, high selectivity may be achieved. However, even though a ratio of hydrogen to carbon is relatively high, an acyclic hydrocarbon may be affected by nitrogen gas more than a cyclic hydrocarbon, and, thus, a hydrocarbon gas source including an acyclic hydrocarbon gas may be used.

In some embodiments of the inventive concept, the hydrocarbon gas may include a hydrocarbon compound with a high sp2 fraction.

For example, the hydrocarbon gas may include a hydrocarbon gas having a ratio of C to H in a range of about 1:1.0 to about 1:2.0. More particularly, the hydrocarbon gas may include at least one of C₂H₂ gas, C₂H₄ gas, and C₆H₁₂ gas.

In addition, the hydrocarbon gas may include a hydrocarbon gas containing a triple bond. More particularly, the hydrocarbon gas may include at least one of acetylene (C₂H₂) gas, propyne (C₃H₄) gas, and butyne (C₄H₆).

The significance of using a hydrocarbon compound with a high sp2 fraction will now be described. High selectivity is affected by a sp2 fraction according to types of bonds between substances in a thin film layer. When a thin film layer has smaller numbers of carbon-hydrogen bonds, the sp2 fraction increases. When the sp2 fraction in the thin film layer increases, the etching selectivity of the thin film layer also increases. Thus, to increase the etching selectivity of a thin film layer, the content of hydrogen in the thin film layer needs to be reduced. Accordingly, to reduce an injection amount of hydrogen, as described above, hydrocarbon gas having a relatively low ratio of hydrogen to carbon may be used as a source gas.

In some embodiments of the inventive concept, a carbon-containing thin film may include an amorphous carbon layer (ACL). Because an ACL may be more easily deposited than a crystalline carbon layer, the manufacturing process may be simplified. Also, the ACL has a higher etching selectivity than a film disposed underneath formed of silicon oxide or silicon nitride.

In some embodiments of the inventive concept, in the deposition process, the amount of nitrogen to carbon included in a carbon-containing thin film may range from about 0.05 at % to about 5.00 at %.

FIG. 20 is a flowchart for explaining a method of manufacturing a semiconductor device according to an embodiment of the inventive concept.

Referring to FIG. 20, in operation 1000, an etching target layer may be deposited on a substrate. In operation 1100, hydrocarbon gas and nitrogen gas may be simultaneously injected into a chamber. In this operation, at least one of oxygen gas and an inert gas may further be injected. In process 1200, a carbon-containing thin film may be formed on the etching target layer. In this operation, a deposition device using plasma may be used. In operation 1300, at least one material layer having different etching properties than the carbon-containing thin film may be formed. In operation 1400, an anti-reflective film may be formed on a lower film. In operation 1500, a resist layer is formed on a lower film. In operation 1600, the resist layer is exposed to light and developed to form patterns. In operation 1700, the carbon-containing thin film exposed through the patterns is etched. In operation 1800, the carbon-containing thin film may be selectively etched according to the patterns. In operation 1900, the etching target layer may be etched according to patterns using the material layer and carbon-containing thin film etched according to the patterns as etch masks.

Referring to FIG. 20, in some embodiments of the inventive concept, one or more of operations 1000, 1300, 1400, and 1700 may be omitted.

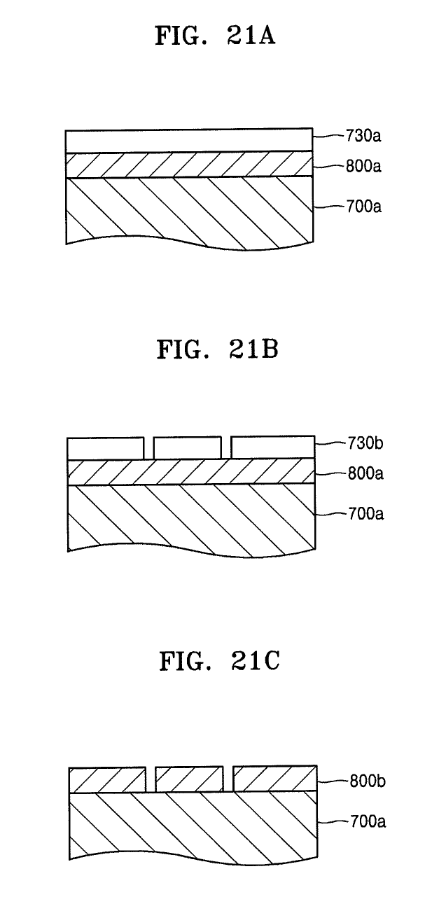

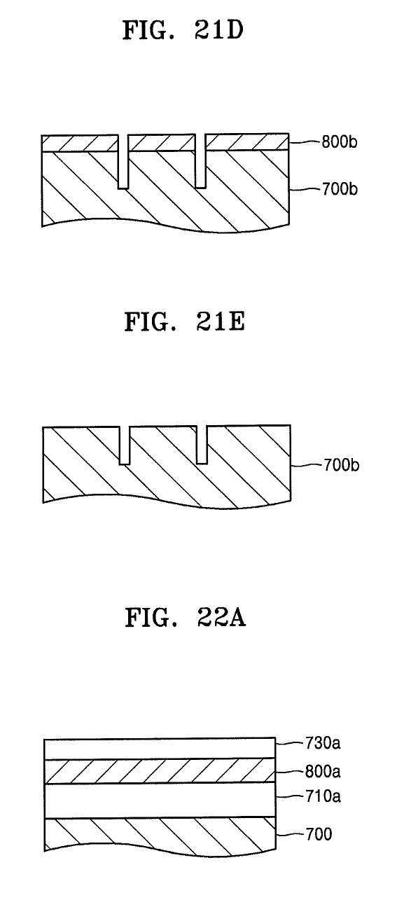

FIGS. 21A to 21E are cross-sectional views sequentially illustrating operations 1600 to 1900 for performing an etching process using a carbon-containing thin film in the method of manufacturing a semiconductor device according to the operations shown in FIG. 20.

Referring to FIG. 21A, a carbon-containing thin film 800a may be deposited on a substrate 700a in operations 1100 and 1200, and a resist layer 730a may then be formed on the carbon-containing thin film 800a in operation 1500.

Referring to FIG. 21B, the resist layer 730a is exposed to light and developed to form resist patterns 730b in operation 1600. The resist patterns 730b may expose a portion of the carbon-containing thin film 800a.

Referring to FIG. 21C, the carbon-containing thin film 800a may be selectively etched using the resist patterns 730b as an etch mask to form carbon-containing thin film patterns 800b in operation 1800.

Referring to FIG. 21D, the substrate 700a is selectively etched to form etched substrate 700b using the carbon-containing thin film patterns 800b as an etch mask in operation 1900. Through this etching process, the carbon-containing thin film patterns 800b may also be etched overall and thus may have a relatively smaller thickness (as compared, for example, with FIG. 21C).

Referring to FIG. 21E, after operation 1900, a process of removing the carbon-containing thin film patterns 800b from the etched substrate 700b may further be performed.

Referring back to FIG. 20, in some embodiments of the inventive concept, one or more of operations 1300, 1400, and 1700 may be omitted.

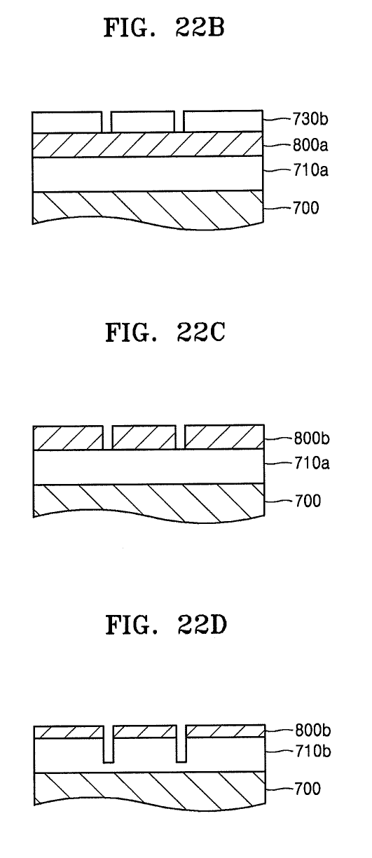

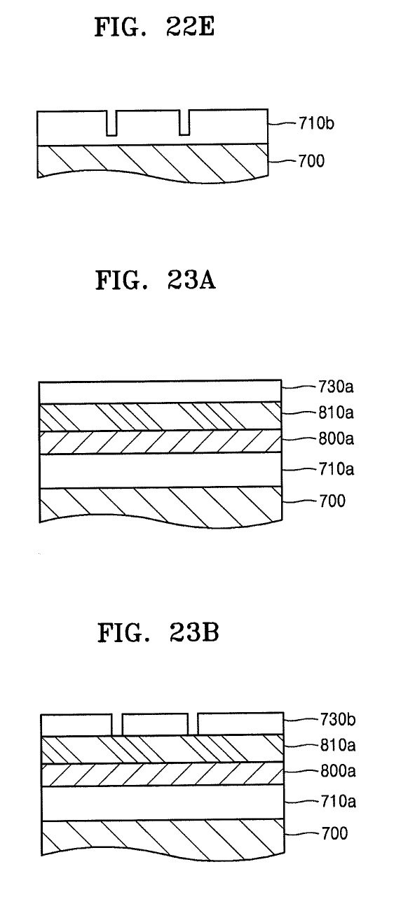

FIGS. 22A to 22E are cross-sectional views sequentially illustrating operations 1600 to 1900 for performing an etching process using a carbon-containing thin film in the method of manufacturing a semiconductor device according to the operations shown in FIG. 20, according to another embodiment of the inventive concept.

In FIGS. 22A to 22E, 23A to 23E, and 24A to 24E, the like reference numerals in FIGS. 21A to 21E denote the same elements.

Referring to FIG. 22A, an etching target layer 710a may be deposited on a substrate 700 in operation 1000. A carbon-containing thin film 800a may be deposited on the etching target layer 710a in operations 1100 and 1200. A resist layer 730a may then be formed on the carbon-containing thin film 800a in operation 1500.

Referring to FIG. 22B, the resist layer 730a is exposed to light and developed to form the resist patterns 730b in operation 1600. The resist patterns 730b may expose a portion of the carbon-containing thin film 800a.

Referring to FIG. 22C, the carbon-containing thin film 800a is selectively etched using the resist patterns 730b as an etch mask to form carbon-containing thin film patterns 800b in operation 1800.

Referring to FIG. 22D, the etching target layer 710a may be selectively etched to form etched target layer 710b using the carbon-containing thin film patterns 800b as an etch mask in operation 1900. Through this etching process, the carbon-containing thin film patterns 800b may also be etched overall and thus may have a relatively smaller thickness (as compared, for example, with FIG. 22C).

Referring to FIG. 22E, after operation 1900, a process of removing the carbon-containing thin film patterns 800b from the etched target layer 710b may further be performed.

Referring back to FIG. 20, in some embodiments of the inventive concept, operation 1400 may be omitted.

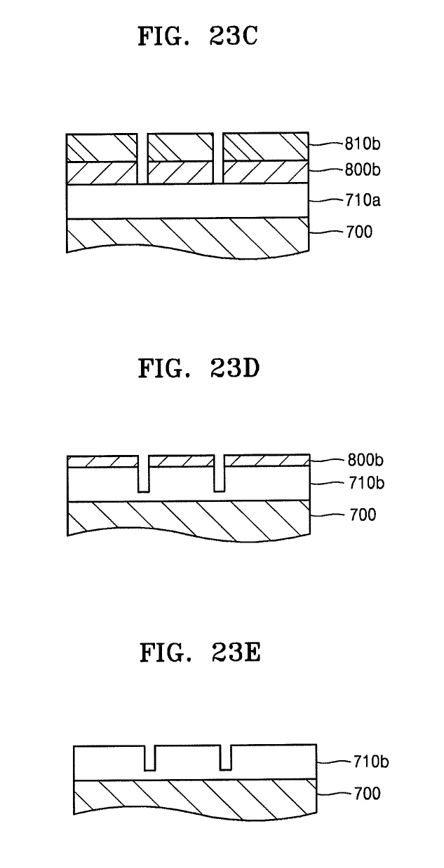

FIGS. 23A to 23E are cross-sectional views sequentially illustrating operations 1600 to 1900 for performing an etching process using a carbon-containing thin film in the method of manufacturing a semiconductor device according to the operations shown in FIG. 20, according to another embodiment of the inventive concept.

Referring to FIG. 23A, an etching target layer 710a may be deposited on a substrate 700 in operation 1000. A carbon-containing thin film 800a may be deposited on the etching target layer 710a in operations 1100 and 1200. In operation 1300, at least one material layer 810a having different etching properties than the carbon-containing thin film 800a may be formed. A resist layer 730a may then be formed on the carbon-containing thin film 800a in operation 1500.

Referring to FIG. 23B, the resist layer 730a is exposed to light and developed to form the resist patterns 730b in operation 1600. The resist patterns 730b may partially expose the material layer 810a.

Referring to FIG. 23C, the carbon-containing thin film 800a is selectively etched using the resist patterns 730b as an etch mask to form material layer patterns 810b and the carbon-containing thin film patterns 800b in operation 1800.

Referring to FIG. 23D, the etching target layer 710a may be selectively etched to form etched target layer 710b using the material layer patterns 810b and the carbon-containing thin film patterns 800b as etch masks in operation 1900. Through these etching processes, the material layer 810a may be etched, and, when the material layer 810a is completely etched, the carbon-containing thin film patterns 800b may also be etched overall and thus may have a relatively smaller thickness (as compared, for example, with FIG. 23C).

Referring to FIG. 23E, after operation 1900, a process of removing the carbon-containing thin film patterns 800b from the etched target layer 710b may further be performed.

Referring back to FIG. 20, in embodiments of the inventive concept, before a resist layer is formed in operation 1500, an anti-reflective film may be formed on a lower film in operation 1400. In the following embodiment, operations 1000, 1300, and 1700 are omitted. In other embodiments, operation 1400 may be performed together with operations 1000, 1300, and 1700.

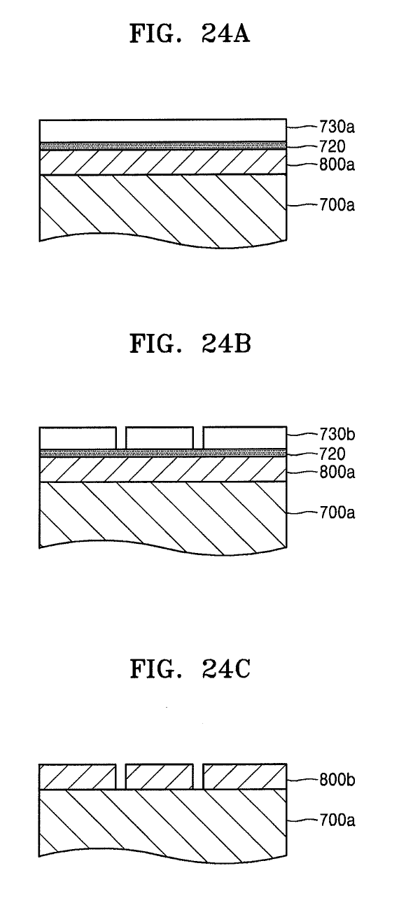

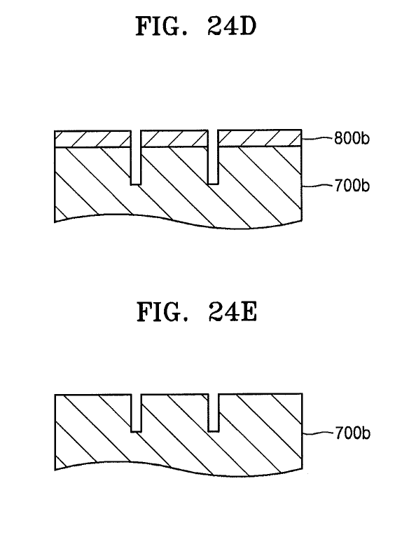

FIGS. 24A to 24E are cross-sectional views sequentially illustrating operations 1600 to 1900 for performing an etching process using a carbon-containing thin film in the method of manufacturing a semiconductor device according to the operations shown in FIG. 20, according to another embodiment of the inventive concept.

Referring to FIG. 24A, an anti-reflective film 720 may be formed in operation 1400 on the carbon-containing thin film 800a deposited according to operations 1100 and 1200. The anti-reflective film 720 is intended to prevent the occurrence of errors in pattern formation due to reflection of light when a resist layer is exposed to light. The resist layer 730a may then be formed in operation 1500.

Referring to FIG. 24B, in operation 1600, the anti-reflective film 720 may be exposed using the etched resist layer 730b that has been exposed to light and developed according to patterns.

Referring to FIG. 24C, in operation 1800, the etched resist layer 730b and the anti-reflective film 720 may be removed, and the carbon-containing thin film 800a may be selectively etched to form etched thin film 800b.

FIGS. 24D and 24E illustrate the same processes as illustrated in FIGS. 21D and 21E. In these processes, the substrate 700a may be etched in accordance with patterns to form etched substrate 700b.

In addition, in the aforementioned embodiment, as a result of etching the etched target layer 710b, at least one of a word line, a bit line, and a metal wire may be obtained; and, thus, the method of manufacturing a memory semiconductor device may be completed.

While the inventive concept has been particularly shown and described with reference to exemplary embodiments thereof, it will be understood that various changes in form and details may be made therein without departing from the spirit and scope of the following claims.

What is claimed is:

1. A method of forming a thin film, the method comprising the steps of:
introducing a substrate into a chamber;
injecting hydrocarbon gas and nitrogen gas simultaneously into the chamber; and
depositing a carbon-containing thin film comprising carbon and nitrogen on the substrate.

2. The method of claim 1, wherein, in the step of depositing the carbon-containing thin film, an amount of nitrogen to carbon included in the carbon-containing thin film ranges from about 0.05 at % to about 5.00 at %.

3. The method of claim 1, further comprising a step of generating plasma in the chamber between the injecting and the depositing steps.

4. The method of claim 1, wherein, in the injecting step, oxygen gas is also injected into the chamber.

5. The method of claim 1, wherein, in the injecting step, at least one inert gas is also injected into the chamber.

6. The method of claim 1, wherein the hydrocarbon gas comprises at least one of an aliphatic hydrocarbon compound, an aromatic hydrocarbon compound, and derivatives thereof.

7. The method of claim 1, wherein the hydrocarbon gas comprises a hydrocarbon gas having a triple chemical bond.

8. The method of claim 1, wherein the hydrocarbon gas is at least one of C₂H₂ gas, C₂H₄ gas, and C₆H₁₂ gas.

9. The method of claim 1, wherein the carbon-containing thin film comprises an amorphous carbon layer.

10. A method of manufacturing a semiconductor device, the method comprising the steps of:
forming a carbon-containing thin film on an etching target layer by simultaneously injecting hydrocarbon gas and nitrogen gas into a chamber;
forming a resist layer on the carbon-containing thin film;
forming a resist pattern by exposing the resist layer to light and developing the exposed resist layer;
forming a carbon-containing thin film pattern to partially expose the etching target layer by selectively etching the carbon-containing thin film according to the resist pattern; and
etching a portion of the exposed etching target layer by using the carbon-containing thin film pattern as an etch mask.

11. The method of claim 10, wherein, in the step of forming the carbon-containing thin film, oxygen gas is also injected into the chamber.

12. The method of claim 10, wherein the etching target layer is a substrate.

13. The method of claim 10, further comprising a step of forming the etching target layer on a substrate before the step of forming the carbon-containing thin film, wherein the etching target layer is a conductive layer, an insulating layer, or a semiconductor layer.

14. The method of claim 10, further comprising a step of forming an anti-reflective film on the carbon-containing thin film between the step of forming the carbon-containing thin film and the step of forming the resist layer.

15. The method of claim 10, further comprising the steps of: forming at least one material layer having different etching properties than the carbon-containing thin film between the step of forming the carbon-containing thin film and the step of forming the resist layer; and also forming a material layer pattern to partially expose the carbon-containing thin film by selectively etching the material layer according to the resist pattern between the step of forming the resist pattern and the step of forming the carbon-containing thin film pattern.

16. A component for use in semiconductor fabrication comprising a carbon-containing thin film having high selectivity and high thickness uniformity deposited on a substrate, the component being formed according to the method of claim 1.

17. A component according to claim 16 wherein the method includes a step of adding oxygen gas or an inert gas to the chamber together with the hydrocarbon gas and nitrogen gas.

18. A semiconductor device fabricated using a thin film having high selectivity and high thickness uniformity, the device being formed according to the method of claim 10.

19. A semiconductor device according to claim 18 wherein, in the step of forming the carbon-containing thin film, oxygen gas or an inert gas is added to the chamber together with the hydrocarbon gas and nitrogen gas.

20. In a method of forming a highly integrated semiconductor device substantially free of micro-patterning errors that comprises the steps of forming a thin film on an etching target layer, etching the thin film to form an etched mask, and etching the target layer using the etched mask, the improvement comprising the step of forming a carbon-containing thin film on the etching target layer by adding hydrocarbon gas and nitrogen gas into a chamber containing the target layer under plasma conditions.
